(19) United States
(12) Patent Application Publication
(10) Pub. No.: US 2020/0202918 A1
(43) Pub. Date: Jun. 25, 2020

(54) THYRISTORS

(71) Applicant: Intel Corporation, Santa Clara, CA (US)

(72) Inventors: Van H. Le, Portland, OR (US); Abhishek A. Sharma, Hillsboro, OR (US); Ravi Pillarisetty, Portland, OR (US)

(73) Assignee: Intel Corporation, Santa Clara, CA (US)

(21) Appl. No.: 16/639,235

(22) PCT Filed: Sep. 14, 2017
(86) PCT No.: PCT/US2017/051486

§ 371 Date: Feb. 14, 2020

(51) Int. Cl. G11C 11/39; H01L 29/74; H01L 27/102; H01L 21/8229

(52) U.S. Cl. CPC G11C 11/39; H01L 21/8229; H01L 27/1027; H01L 29/74

(57) ABSTRACT

Disclosed herein are thyristors and related devices and techniques. In some embodiments, an integrated circuit (IC) device may include a metal portion and a thyristor on the metal portion. The thyristor may include a stack of alternating p-type and n-type material layers, and the stack may be on the metal portion.

### BACKGROUND

A thyristor is a device that acts as a bistable switch. In an off state, a thyristor may exhibit high resistance; in an on state, a thyristor may exhibit low resistance,

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, not by way of limitation, in the figures of the accompanying drawings.

FIG. 1A is a perspective view of a portion of a memory array including a thyristor, in accordance with various embodiments.

FIG. 1B is a schematic illustration of a thyristor of the memory array of FIG. 1A, in accordance with various embodiments.

FIG. 1C is a plot depicting example characteristic voltages of the thyristor of FIGS. 1A and 1B, in accordance with various embodiments.

FIG. 2 is a cross-sectional view of an example thyristor, in accordance with various embodiments.

FIGS. 3A-3D are cross-sectional views of stages in an example process of manufacturing a thyristor, in accordance with various embodiments.

FIG. 4 is a schematic illustration of a memory device including thyristors, in accordance with various embodiments.

FIG. 5 is a flow diagram of an illustrative method of manufacturing a thyristor, in accordance with various embodiments.

FIG. 6 depicts top views of a wafer and dies that may include any of the thyristors disclosed herein.

FIG. 7 is a cross-sectional side view of an integrated circuit (IC) device that may include any of the thyristors disclosed herein.

FIG. 8 is a cross-sectional side view of a device assembly that may include any of the thyristors disclosed herein.

FIG. 9 is a block diagram of an example computing device that may include any of the thyristors disclosed herein, in accordance with various embodiments.

### DETAILED DESCRIPTION

Disclosed herein are thyristors and related devices and techniques. In some embodiments, an integrated circuit (IC) device may include a metal portion and a thyristor on the metal portion. The thyristor may include a stack of alternating p-type and n-type material layers, and the stack may be on the metal portion.

Some memory devices may be considered “standalone” devices in that they are included in a chip that does not also include computing logic (e.g., transistors for performing processing operations). Other memory devices may be included in a chip along with computing logic and may be referred to as “embedded” memory devices. Using embedded memory to support computing logic may improve performance by bringing the memory and the computing logic closer together and eliminating interfaces that increase latency. However, certain existing memory technologies require fabrication in a “front-end” device layer on a semiconductor substrate (e.g., on a silicon wafer) and thus may not be readily formed in the “back-end” metallization stack of an IC device. Additionally, back end of line (BEOL) manufacturing often imposes smaller thermal budgets than device layer fabrication, and thus memory technologies whose fabrication requires higher front-end temperatures may not be formed in the BEOL,

Various ones of the thyristors and/or memory arrays disclosed herein may be fabricated on metal and thus may enable the use of high density embedded memory in computing chips. For example, various ones of the thyristors disclosed herein may include group IV or group III-V semiconductors grown on a metal (e.g., on a metal interconnect). Such thyristors may be used in high density volatile random access memory (RAM) applications whose footprint is smaller, and density larger, than conventional dynamic random access memory (DRAM).

In the following detailed description, reference is made to the accompanying drawings that form a part hereof, and in which is shown, by way of illustration, embodiments that may be practiced. It is to be understood that other embodiments may be utilized and structural or logical changes may be made without departing from the scope of the present disclosure. Therefore, the following detailed description is not to be taken in a limiting sense.

Various operations may be described as multiple discrete actions or operations in turn in a manner that is most helpful in understanding the claimed subject matter. However, the order of description should not be construed as to imply that these operations are necessarily order dependent, In particular, these operations may not be performed in the order of presentation. Operations described may be performed in a different order from the described embodiment, Various additional operations may be performed, and/or described operations may be omitted in additional embodiments.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). The term “between,” when used with reference to measurement ranges, is inclusive of the ends of the measurement ranges. As used herein, the notation “A/B/C” means (A), (B), and/or (C). As used herein, a “dopant” refers to an impurity material that is included in another material to alter the electrical properties of the other material. As used herein, an “embedded memory” refers to a memory device or array of devices that is included in a die along with computing logic (e.g., transistors arranged to perform processing operations).

The description uses the phrases “in an embodiment” or “in embodiments,” which may each refer to one or more of the same or different embodiments. Furthermore, the terms “comprising,” “including,” “having,” and the like, as used with respect to embodiments of the present disclosure, are synonymous. The disclosure may use perspective-based descriptions such as “above,” “below,” “top,” “bottom,” and “side”; such descriptions are used to facilitate the discussion and are not intended to restrict the application of disclosed embodiments. The disclosure may use the singular term “layer,” but the term “layer” should be understood to refer to assemblies that may include multiple different material layers. The accompanying drawings are not necessarily drawn to scale.

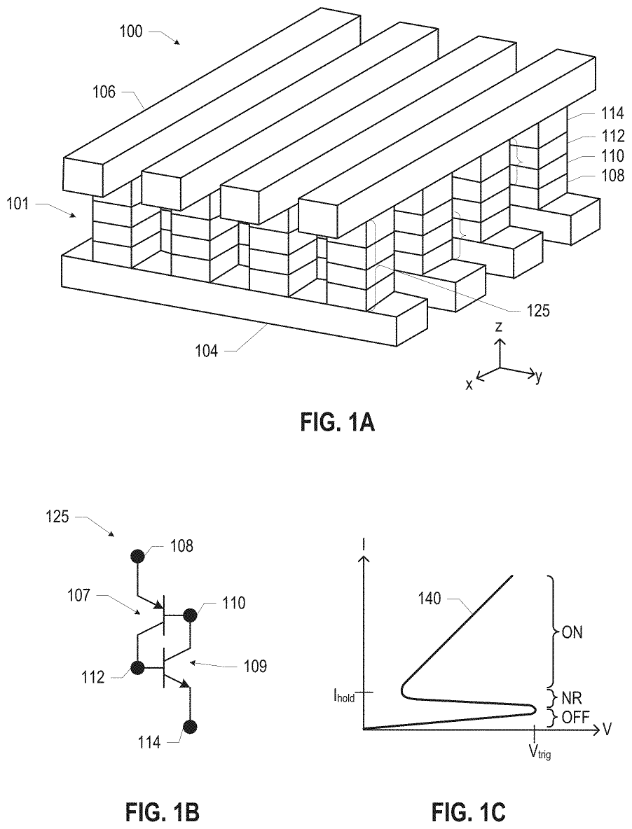

FIG. 1A is a perspective view of a portion of a memory array 100 including a thyristor 125, in accordance with various embodiments. The memory arrays 100 and the thyristors 125 disclosed herein may be included in any suitable IC device, such as any of those discussed below. The memory array 100 may be a cross-point memory array including thyristors 125 located at the intersections of conductive lines 104 and conductive lines 106. The conductive lines 104 may be located in one interconnect layer of a metallization stack (discussed further below), and the conductive lines 106 may be located in another, higher interconnect layer of the metallization stack. In some embodiments, the conductive lines 104 may be word lines and the conductive lines 106 may be bit lines, for example; for ease of discussion, this terminology may be used herein to refer to the conductive lines 104 and the conductive lines 106. In other embodiments, the conductive lines 104 may be bit lines and the conductive lines 106 may be word lines.

In the embodiment illustrated in FIG. 1A, the word lines 104 may be parallel to each other and may be arranged perpendicularly to the bit lines 106 (which themselves may be parallel to each other), but any other suitable arrangement may be used. The word lines 104 and/or the bit lines 106 may be formed of any suitable conductive material, such as a metal (e.g., tungsten, copper, titanium, or aluminum). In some embodiments, the memory array 100 depicted in FIG. 1A may be a portion (e.g., a deck 101) of a three-dimensional array in which other arrangements of thyristors 125 like the arrangement in the memory array 100 of FIG. 1A are located at different levels (e.g., above or below the depicted memory array 100). The memory arrays 100 disclosed herein may include one or more decks 101 (e.g., two, three, or four decks 101). As discussed further below, in some embodiments, the memory array 100 may be included in a back-end of the IC device 105 (e.g., in the metallization stack above a device layer, as discussed below with reference to FIG. 7).

The thyristors 125 may include a stack of alternating p-type and n-type material layers 108-114. For example, FIG. 1 illustrates thyristors 125 including a p-type material layer 108 on the word line 104, an n-type material layer 110 on the p-type material layer 108, a p-type material layer 112 on the n-type material layer 110, and an n-type material layer 114 on the p-type material layer 112. Note that the orientation of the arrangement of the p-type and n-type material layers in FIG. 1 is simply illustrative, and in some embodiments, the orientation may be reversed: the n-type material layer 114 may be on the word line 104, the p-type material layer 112 may be on the n-type material layer 114, the n-type material layer 110 may be on the p-type material layer 112, and the p-type material layer 108 may be on the n-type material layer 110. Note that, although some of the thyristors 125 discussed herein may be shown as having a total of four p-type/n-type material layers (as illustrated in FIG. 1), this is simply for ease of illustration, and the thyristors 125 disclosed herein may have more than four p-type/n-type material layers (e.g., 8, 12, or 16 p-type/n-type material layers). In such embodiments, the additional p-type/n-type material layers may take the form of the p-type and n-type material layers 108-112 discussed herein. The thyristors 125 of FIG. 1 may be referred to as “vertical thyristors” because the stacks of alternating p-type and n-type material layers 108-114 may be oriented in the z-direction in an IC device (e.g., extending between the conductive lines 104 and 106 located in different interconnect layers of a metallization stack).

The thyristor 125 may be a two-terminal device that may act as a bistable switch. The stack of alternating p-type and n-type material layers 108-114 may act as a pair of coupled bipolar junction transistors 107 and 109, as illustrated in the schematic view of FIG. 1B. When the thyristor 125 is in a highly conductive (i.e., low resistance) state, the “switch” may be closed; when the thyristor 125 is in a less conductive (i.e., high resistance) state, the “switch” may be open.

The state of the thyristor 125 may change in response to the voltage applied across and/or the current through the thyristor 125. FIG. 1C illustrates an example I-V characteristic 140 of an example thyristor 125 when positive voltages are applied. As illustrated in FIG. 1C, the thyristors 125 may act as resistive storage elements. In particular, the thyristor 125 may be programmed to a particular resistance state by applying an electric field or other energy (e.g., positive or negative voltage or current pulses, as discussed below) to the thyristor 125. During operation, the thyristor 125 may be switched between two different non-volatile states: a high resistance or “OFF” state and a low resistance or “ON” state. The state of the thyristor 125 may be used to represent a data bit (e.g., a “1” for ON and a “0” for OFF, or vice versa). The thyristor 125 may have a voltage threshold Vtrig beyond which the thyristor 125 is in the ON state. Similarly, a thyristor 125 may have a current threshold IhoId below which the thyristor 125 is in the OFF state. Between the ON state and the OFF state, the thyristor may exhibit a transitory negative resistance state, as illustrated in FIG. 1C.

Disclosed herein are thyristors 125 that may be disposed on a metal (e,g,, a metal interconnect, such as a metal conductive line or a metal conductive via). Some conventional thyristors may only be fabricated on a semiconductor material and thus may not be readily included in a metallization stack of an IC device (e.g., in a back-end memory array, as discussed further below). As noted above, the thyristors 125 disclosed herein may thus be used in embedded applications (e.g., by including the thyristors 125 in a memory array 100 in the back-end of a die that also includes computing logic, as discussed below).

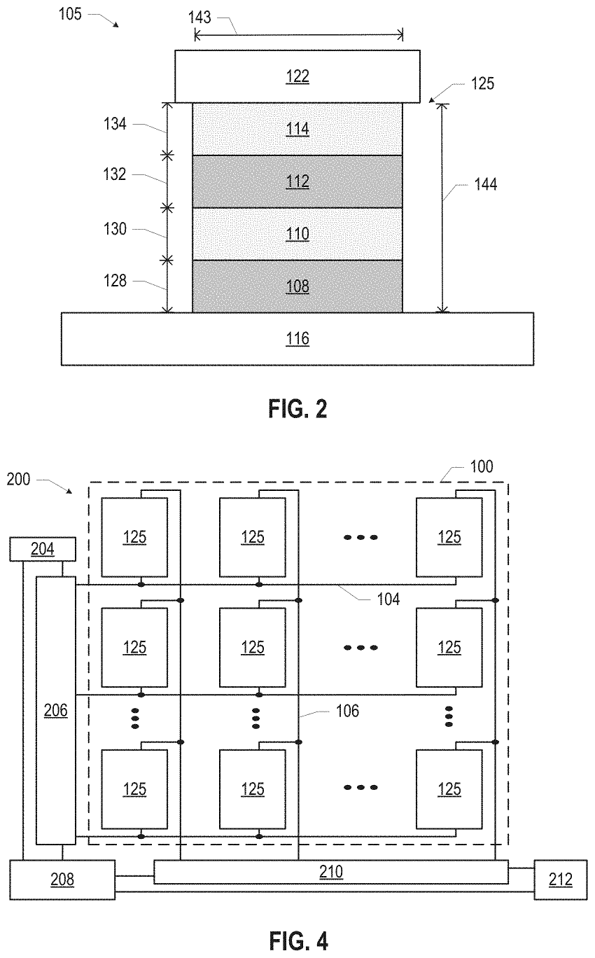

The thyristors 125 disclosed herein may take any of a number of forms. For example, FIG. 2 is a cross-sectional view of a portion of an IC device 105 including a thyristor 125, in accordance with various embodiments. The IC device 105 may be any suitable IC device, such as any of those disclosed herein. In some embodiments, the portion of the IC device 105 illustrated in FIG. 2 may be a portion of the memory array 100 of FIG. 1, as discussed further below.

The thyristor 125 of FIG. 2 may include a p-type material layer 108, an n-type material layer 110 on the p-type material layer 108, a p-type material layer 112 on the n-type material layer 110, and an n-type material layer 114 on the p-type material layer 112. The p-type material layer 108 may be disposed on a metal portion 116, and a metal portion 122 may be disposed on the n-type material layer 114. Note that, as discussed above with reference to FIG. 1, the orientation of the arrangement of the p-type and n-type material layers in FIG. 2 is simply illustrative, and in some embodiments, the orientation may be reversed: the n-type material layer 114 may be on the metal portion 116, the p-type material layer 112 may be on the n-type material layer 114, the n-type material layer 110 may be on the p-type material layer 112, the p-type material layer 108 may be on the n-type material layer 110, and the metal portion 122 may be on the p-type material layer 108. Additionally, as noted above, the thyristor 125 may include more than four p-type/n-type material layers.

The metal portions 116 and 122 may include any suitable metals. For example, in some embodiments, the metal portions 116 and/or 122 may include gold, nickel, tantalum, platinum, hafnium, cobalt, indium, iridium, copper, tungsten, ruthenium, and/or palladium. The metal portions 116 and/or 122 may be composed of pure forms of these elements, combinations of these elements, or combinations of these elements and other elements, in some embodiments. For example, in some embodiments, the metal portions 116 and/or 122 may include a conductive nitride (e.g., tantalum nitride or titanium nitride). In some embodiments, the material compositions of the metal portions 116 and 122 may be the same, while in other embodiments, the material compositions of the metal portions 116 and 122 may be different.

In some embodiments, the metal portions 116 and 122 may be or include interconnects, such as conductive lines and/or conductive vias, as discussed below. For example, the metal portion 116 may be the conductive line 104 of the memory array 100 of FIG. 1, and the metal portion 122 may be the conductive line 106 of the memory array 100 of FIG. 1. The metal portion 116 may be a conductive line oriented left-right in the plane of the drawing of FIG. 2, while the metal portion 122 may be a conductive line oriented in-out of the plane of the drawing of FIG. 2.

The p-type material layers 108 and 112 and the n-type material layer 110 and 114 may include any suitable materials. In some embodiments, one or more of the p-type/n-type material layers 108-114 may include a group IV material, such as silicon, germanium, tin, combinations of these materials (e.g., silicon germanium or germanium tin), or combinations of these materials and other materials. In some embodiments, one or more of the p-type/n-type material layers 108-114 may include a group III-V material, such as binary or ternary group Ill-V materials (including, e.g., gallium, arsenic, antimony, indium, phosphorus, aluminum, aluminum arsenide, aluminum antimonide, gallium arsenide, gallium antimonide, indium phosphide, indium gallium arsenide, aluminum gallium arsenide, indium aluminum arsenide, aluminum arsenic antimonide, aluminum gallium antimonide, indium gallium antimonide, or gallium arsenic antimonide), combinations of these materials, or combinations of these materials and other materials.

The p-type/n-type material layers 108-114 may each include a dopant to achieve a p-type conductivity or an n-type conductivity, as appropriate. Appropriate dopants may depend on the base material of the p-type/n-type material layer (e.g., whether the p-type/n-type material layer includes a group IV material or a group III-V material). When a p-type material layer 108/112 includes a group IV material (e.g., silicon or germanium), the dopant may include boron, aluminum, gallium, or indium. When an n-type material layer 110/114 includes a group IV material, the dopant may include phosphorous, arsenic, or antimony. When a p-type material layer 108/112 includes a group III-V material, the dopant may include beryllium, zinc, magnesium, cadmium, or carbon. When an n-type material layer 110/114 includes a group III-V material, the dopant may include silicon, germanium, tin, tellurium, sulfur, or selenium. In some embodiments, the concentration of dopants in the p-type/n-type material layers 108-114 may be between 1e17 atoms/cm³ and 1e21 atoms/cm³. The material compositions of the p-type/n-type material layers 108-114 may, among other factors, help determine the threshold voltage Vtrig and the holding current Ihold.

The thicknesses of the material layers included in the thyristor 125 of FIG. 2 may take any suitable values. For example, in some embodiments, the p-type material layer 108 may have a thickness 128 between 1 nanometer and 100 nanometers, the n-type material layer 110 may have a thickness 130 between 1 nanometer and 100 nanometers, the p-type material layer 112 may have a thickness 132 between 1 nanometer and 100 nanometers, and the n-type material layer 114 may have a thickness 134 between 1 nanometer and 100 nanometers. The thicknesses 128-134 of the p-type/n-type material layers 108-114 may, among other factors, help determine the threshold voltage Vtrig and the holding current Ihold. The thyristor 125 may have a width 143 between 10 nanometers and 100 nanometers. In some embodiments, an aspect ratio of the thyristor 125 (i.e., the ratio of the width 143 to the total height 144) may be between 1:5 and 1:20 (e.g., 1:10).

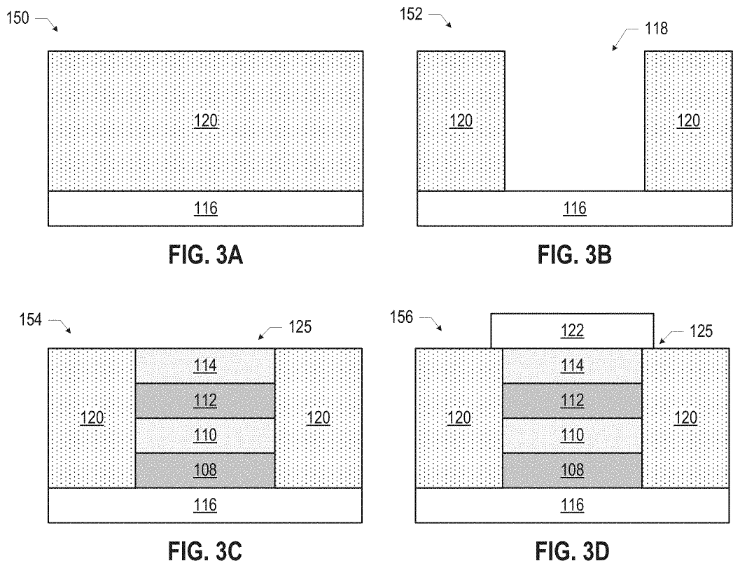

The thyristors 125 disclosed herein may be manufactured using any suitable technique. For example, FIGS. 3A-3D illustrate various stages in an example process of manufacturing the thyristor 125 of FIG. 2. Various operations illustrated in FIGS. 3A-3D may be repeated, omitted, or performed in a different order, in accordance with the embodiments disclosed herein. Additionally, FIGS. 3A-3D illustrate only the manufacture of a single thyristor 125, but it is understood that multiple thyristors 125 may be formed in parallel in accordance with the techniques of FIGS. 3A-3D, and multiple sets of thyristors 125 may be formed in series by repeating the operations of FIGS. 3A-3D.

FIG. 3A is a side cross-sectional view of an assembly 150 including a dielectric material 120 disposed on a metal portion 116. The metal portion 116 may take any of the forms disclosed herein (e.g., a conductive line or via). The dielectric material 120 may include any suitable dielectric. For example, in embodiments in which the thyristor 125 is formed in the back-end of an IC device, the dielectric material 120 may be an interlayer dielectric, such as silicon oxide. A thickness of the dielectric material 120 in the assembly 150 may be equal to or greater than the desired total height 144 of the thyristor 125.

FIG. 3B is a side cross-sectional view of an assembly 152 subsequent to forming a cavity 118 in the dielectric material 120 of the assembly 150 (FIG. 3A). The cavity 118 may have a width equal to the desired width 143 of the thyristor 125 and may extend down to the metal portion 116, so that some of the metal portion 116 is exposed at the bottom of the cavity 118. Any suitable patterning technique may be used to form the cavity 118 (e.g., deposition of a photoresist, lithographic patterning of the photoresist, etching the dielectric material 120 in accordance with the patterned photoresist, and removal of any remaining photoresist).

FIG. 3C is a side cross-sectional view of an assembly 154 subsequent to forming the p-type/n-type material layers 108-114 in the cavity 118 of the assembly 152 (FIG. 3B). The p-type material layer 108 may be formed first on the exposed metal portion 116 at the bottom of the cavity 118 using a vapor-liquid-solid (VLS) growth technique (also known as a “metal-assisted epitaxy” technique). In such techniques, a liquid alloy may first be introduced to the exposed metal portion 116, and then a vapor including the material of the p-type material layer 108 (e.g., a group IV or group III-V material, and a dopant) may be introduced; the liquid alloy may adsorb the vapor, and crystal growth of the material of the p-type material layer 108 may then begin, The metal portion 116 may act as a catalyst for this growth, allowing the growth to take place at temperatures that are compatible with BEOL operations, enabling the thyristor 125 to be formed in the back-end of a device. After the p-type material layer 108 has been formed, the material composition of the introduced vapor may be changed so as to form the n-type material layer 110 on the p-type material layer 108. This process may continue to form the p-type material layer 112 and the n-type material layer 114. In some embodiments, the resulting assembly may then be polished (e.g., using a chemical mechanical polishing technique) to planarize the top surface.

FIG. 3D is a side cross-sectional view of an assembly 156 subsequent to forming the metal portion 122 on the top surface of the assembly 154 (FIG. 3C). The metal portion 122 may be in contact with the n-type material layer 114, as shown. The metal portion 122 may be formed using any suitable technique, such as an additive technique, a subtractive technique, a semi-additive technique, or a dual Damascene technique. As noted above, the metal portion 122 may be a conductive via or line, for example. In some embodiments, the operations of FIGS. 3A-3D may be used to form a deck 101 of a memory array 100 and may be repeated to form additional decks 101, as desired.

A memory array 100 including thyristors 125 may be controlled in any suitable manner. For example, FIG. 4 is a schematic illustration of a memory device 200 including a memory array 100 having thyristors 125 as storage elements, in accordance with various embodiments. The memory device 200 of FIG. 4 may be a bidirectional cross-point memory array in which each column is associated with a bit line 106 driven by column select circuitry 210. Each row may be associated with a word line 104 driven by row select circuitry 206. During operation, read/write control circuitry 208 may receive memory access requests (e.g., from one or more processing devices or communication chips of a computing device, such as the computing device 2000 discussed below) and may respond by generating an appropriate control signal (e,g,, read, write 0, or write 1), as known in the art. The read/write control circuitry 208 may control the row select circuitry 206 and the column select circuitry 210 to select the desired thyristor 125. Voltage/current supplies 204 and 212 may be controlled to provide the voltage(s) and/or current(s) necessary to bias the memory array 100 to facilitate the requested action on one or more thyristors 125. Row select circuitry 206 and column select circuitry 210 may apply appropriate voltages across the memory array 100 to access the selected thyristors 125 (e.g., by providing appropriate voltages to the thyristors 125 to allow the desired thyristors 125 to conduct). Row select circuitry 206, column select circuitry 210, and read/write control circuitry 208 may be implemented using any devices and techniques known in the art.

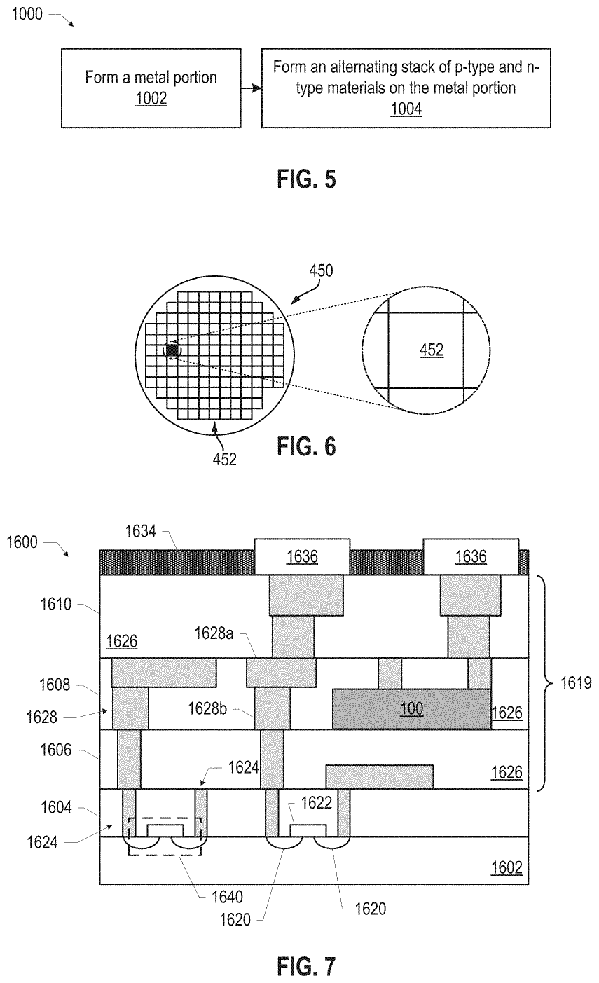

As noted above, any suitable techniques may be used to manufacture the thyristors 125 disclosed herein. FIG. 5 is a flow diagram of an illustrative method 1000 of manufacturing a thyristor, in accordance with various embodiments. Although the operations discussed below with reference to the method 1000 are illustrated in a particular order and depicted once each, these operations may be repeated or performed in a different order (e.g., in parallel), as suitable. Additionally, various operations may be omitted, as suitable. Various operations of the method 1000 may be illustrated with reference to one or more of the embodiments discussed above, but the method 1000 may be used to manufacture any suitable thyristor (including any suitable ones of the embodiments disclosed herein).

At 1002, a metal portion may be formed. For example, the metal portion 116 (e.g., a via, a word line 104 or bit line 106, or any combination of metal interconnects) may be formed using an additive, subtractive, semi-additive, or dual Damascene technique.

At 1004, an alternating stack of n-type and p-type materials may be formed on the metal portion. For example, the p-type/n-type material layers 108-114 may be formed on the metal portion using a VLS method, in accordance with any of the embodiments disclosed herein.

The thyristors 125 and memory arrays 100 disclosed herein may be included in any suitable electronic device. FIG. 6 depicts top views of a wafer 450 and dies 452 that may be formed from the wafer 450; the dies 452 may include any of the thyristors 125 or memory arrays 100 disclosed herein. The wafer 450 may include semiconductor material and may include one or more dies 452 having IC elements (e.g., thyristors 125) formed on or above a surface of the wafer 450. Each of the dies 452 may be a repeating unit of a semiconductor product that includes any suitable device (e.g., the memory device 200), After the fabrication of the semiconductor product is complete, the wafer 450 may undergo a singulation process in which the dies 452 are separated from one another to provide discrete “chips” of the semiconductor product. A die 452 may include one or more thyristors 125 or memory arrays 100 and/or supporting circuitry to route electrical signals to the thyristors 125 or memory arrays 100 (e.g., interconnects including conductive lines 104 and 106), as well as any other IC components. In some embodiments, the wafer 450 or the die 452 may include other memory devices, logic devices (e.g., AND, OR, NAND, or NOR gates), or any other suitable circuit element. Multiple ones of these devices may be combined on a single die 452. For example, a memory device formed by multiple memory arrays (e.g., multiple memory arrays 100) may be formed on a same die 452 as a processing device (e.g., the processing device 2002 of FIG. 9) or other logic that is configured to store information in the memory devices or execute instructions stored in the memory array,

FIG. 7 is a cross-sectional side view of an IC device 1600 that may include any of the thyristors 125 or memory arrays 100 disclosed herein, The IC device 1600 may be formed on a substrate 1602 (e.g., the wafer 450 of FIG. 6) and may be included in a die (e.g., the die 452 of FIG. 6). The substrate 1602 may be a semiconductor substrate composed of semiconductor material systems including, for example, n-type or p-type materials systems (or a combination of both). The substrate 1602 may include, for example, a crystalline substrate formed using a bulk silicon or a silicon-on-insulator (SOI) substructure. In some embodiments, the substrate 1602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, or IV may also be used to form the substrate 1602. Although a few examples of materials from which the substrate 1602 may be formed are described here, any material that may serve as a foundation for an IC device 1600 may be used. The substrate 1602 may be part of a singulated die (e.g., the dies 452 of FIG. 6) or a wafer (e.g., the wafer 450 of FIG. 6).

The IC device 1600 may include one or more device layers 1604 disposed on the substrate 1602. The device layer 1604 may include features of one or more transistors 1640 (e.g., metal oxide semiconductor field-effect transistors (MOSFETs)) formed on the substrate 1602. The device layer 1604 may include, for example, one or more source and/or drain (S/D) regions 1620, a gate 1622 to control current flow in the transistors 1640 between the S/D regions 1620, and one or more S/D contacts 1624 to route electrical signals to/from the S/D regions 1620. The transistors 1640 may include additional features not depicted for the sake of clarity, such as device isolation regions, gate contacts, and the like, The transistors 1640 are not limited to the type and configuration depicted in FIG. 6 and may include a wide variety of other types and configurations such as, for example, planar transistors, non-planar transistors, or a combination of both, Non-planar transistors may include FinFET transistors, such as double-gate transistors or tri-gate transistors, and wrap-around or all-around gate transistors, such as nanoribbon and nanowire transistors,

Each transistor 1640 may include a gate 1622 formed of at least two layers, a gate dielectric and a gate electrode. The gate dielectric may include one layer or a stack of layers, The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process may be carried out on the gate dielectric to improve its quality when a high-k material is used.

The gate electrode may be formed on the gate dielectric and may include at least one p-type work function metal or n-type work function metal, depending on whether the transistor 1640 is to be a p-type metal oxide semiconductor (PMOS) or an n-type metal oxide semiconductor (NMOS) transistor. In some implementations, the gate electrode may consist of a stack of two or more metal layers, where one or more metal layers are work function metal layers and at least one metal layer is a fill metal layer. Further metal layers may be included for other purposes, such as a barrier layer. For a PMOS transistor, metals that may be used for the gate electrode include, but are not limited to, ruthenium, palladium, platinum, cobalt, nickel, and conductive metal oxides (e.g., ruthenium oxide), and any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, and carbides of these metals (e.g., hafnium carbide, zirconium carbide, titanium carbide, tantalum carbide, and aluminum carbide), and any of the metals discussed above with reference to a PMOS transistor (e.g., for work function tuning).

In some embodiments, when viewed as a cross-section of the transistor 1640 along the source-channel-drain direction, the gate electrode may consist of a U-shaped structure that includes a bottom portion substantially parallel to the surface of the substrate and two sidewall portions that are substantially perpendicular to the top surface of the substrate. In other embodiments, at least one of the metal layers that form the gate electrode may simply be a planar layer that is substantially parallel to the top surface of the substrate and does not include sidewall portions substantially perpendicular to the top surface of the substrate. In other embodiments, the gate electrode may consist of a combination of U-shaped structures and planar, non-U-shaped structures. For example, the gate electrode may consist of one or more U-shaped metal layers formed atop one or more planar, non-U-shaped layers.

In some embodiments, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and silicon oxynitride. Processes for forming sidewall spacers are well known in the art and generally include deposition and etching process steps. In some embodiments, a plurality of spacer pairs may be used; for instance, two pairs, three pairs, or four pairs of sidewall spacers may be formed on opposing sides of the gate stack.

The S/D regions 1620 may be formed within the substrate 1602 adjacent to the gate 1622 of each transistor 1640. The S/D regions 1620 may be formed using an implantation/diffusion process or an etching/deposition process, for example. In the former process, dopants such as boron, aluminum, antimony, phosphorous, or arsenic may be ion-implanted into the substrate 1602 to form the S/D regions 1620. An annealing process that activates the dopants and causes them to diffuse farther into the substrate 1602 may follow the ion-implantation process. In the latter process, the substrate 1602 may first be etched to form recesses at the locations of the S/D regions 1620. An epitaxial deposition process may then be carried out to fill the recesses with material that is used to fabricate the S/D regions 1620. In some implementations, the S/D regions 1620 may be fabricated using a silicon alloy such as silicon germanium or silicon carbide. In some embodiments, the epitaxially deposited silicon alloy may be doped in situ with dopants such as boron, arsenic, or phosphorous. In some embodiments, the S/D regions 1620 may be formed using one or more alternate semiconductor materials such as germanium or a group Ill-V material or alloy. In further embodiments, one or more layers of metal and/or metal alloys may be used to form the S/D regions 1620.

Electrical signals, such as power and/or input/output (I/O) signals, may be routed to and/or from the devices (e.g., transistors 1640) of the device layer 1604 through one or more interconnect layers disposed on the device layer 1604 (illustrated in FIG. 7 as interconnect layers 1606-1610). For example, electrically conductive features of the device layer 1604 (e.g., the gate 1622 and the S/D contacts 1624) may be electrically coupled with the interconnect structures 1628 of the interconnect layers 1606-1610. The one or more interconnect layers 1606-1610 may form a metallization stack (also referred to as an “ILD stack”) 1619 of the IC device 1600.

In some embodiments, one or more thyristors 125 or memory arrays 100 may be disposed in one or more of the interconnect layers 1606-1610, in accordance with any of the techniques disclosed herein. FIG. 6 illustrates a single memory array 100 in the interconnect layer 1608 for illustration purposes, but any number and structure of memory arrays 100 and/or thyristors 125 may be included in any one or more of the layers in a metallization stack 1619 (e.g., memory arrays 100 with one or more decks 101 of thyristors 125). A memory array 100 included in the metallization stack 1619, in combination with computing logic (e.g., some or all of the transistors 1640) in the IC device 1600, may be referred to as an “embedded” memory array, as discussed above. In embodiments in which the IC device 1600 does not include any computing logic, but does include one or more memory arrays 100, the IC device 1600 may be referred to as a “standalone” memory device. One or more thyristors 125 and/or memory arrays 100 in the metallization stack 1619 may be coupled to any suitable ones of the devices in the device layer 1604, and/or to one or more of the conductive contacts 1636 (discussed below).

The interconnect structures 1628 may be arranged within the interconnect layers 1606-1610 to route electrical signals according to a wide variety of designs (in particular, the arrangement is not limited to the particular configuration of interconnect structures 1628 depicted in FIG. 6). Although a particular number of interconnect layers 1606-1610 is depicted in FIG. 6, embodiments of the present disclosure include IC devices having more or fewer interconnect layers than depicted.

In some embodiments, the interconnect structures 1628 may include lines 1628a and/or vias 1628b filled with an electrically conductive material such as a metal. The lines 1628a may be arranged to route electrical signals in a direction of a plane that is substantially parallel with a surface of the substrate 1602 upon which the device layer 1604 is formed. For example, the lines 1628a may route electrical signals in a direction in and out of the page from the perspective of FIG. 6. The vias 1628b may be arranged to route electrical signals in a direction of a plane that is substantially perpendicular to the surface of the substrate 1602 upon which the device layer 1604 is formed. In some embodiments, the vias 1628b may electrically couple lines 1628a of different interconnect layers 1606-1610 together.

The interconnect layers 1606-1610 may include a dielectric material 1626 disposed between the interconnect structures 1628, as shown in FIG. 6. In some embodiments, the dielectric material 1626 disposed between the interconnect structures 1628 in different ones of the interconnect layers 1606-1610 may have different compositions; in other embodiments, the composition of the dielectric material 1626 between different interconnect layers 1606-1610 may be the same.

A first interconnect layer 1606 (referred to as Metal 1 or “M1”) may be formed directly on the device layer 1604. In some embodiments, the first interconnect layer 1606 may include lines 1628a and/or vias 1628b, as shown. The lines 1628a of the first interconnect layer 1606 may be coupled with contacts (e.g., the S/D contacts 1624) of the device layer 1604.

A second interconnect layer 1608 (referred to as Metal 2 or “M2”) may be formed directly on the first interconnect layer 1606. In some embodiments, the second interconnect layer 1608 may include vias 1628b to couple the lines 1628a of the second interconnect layer 1608 with the lines 1628a of the first interconnect layer 1606, Although the lines 1628a and the vias 1628b are structurally delineated with a line within each interconnect layer (e.g., within the second interconnect layer 1608) for the sake of clarity, the lines 1628a and the vias 1628b may be structurally and/or materially contiguous (e.g., simultaneously filled during a dual Damascene process) in some embodiments.

A third interconnect layer 1610 (referred to as Metal 3 or “M3”) (and additional interconnect layers, as desired) may be formed in succession on the second interconnect layer 1608 according to similar techniques and configurations described in connection with the second interconnect layer 1608 or the first interconnect layer 1606, In some embodiments, the interconnect layers that are “higher up” in the metallization stack 1619 in the IC device 1600 (i.e., farther away from the device layer 1604) may be thicker.

The IC device 1600 may include a solder resist material 1634 (e.g., polyimide or similar material) and one or more conductive contacts 1636 formed on the interconnect layers 1606-1610. In FIG. 6, the conductive contacts 1636 are illustrated as taking the form of bond pads. The conductive contacts 1636 may be electrically coupled with the interconnect structures 1628 and configured to route the electrical signals of the transistor(s) 1640 to other external devices. For example, solder bonds may be formed on the one or more conductive contacts 1636 to mechanically and/or electrically couple a chip including the IC device 1600 with another component (e.g., a circuit board). The IC device 1600 may include additional or alternate structures to route the electrical signals from the interconnect layers 1606-1610; for example, the conductive contacts 1636 may include other analogous features (e.g., posts) that route the electrical signals to external components.

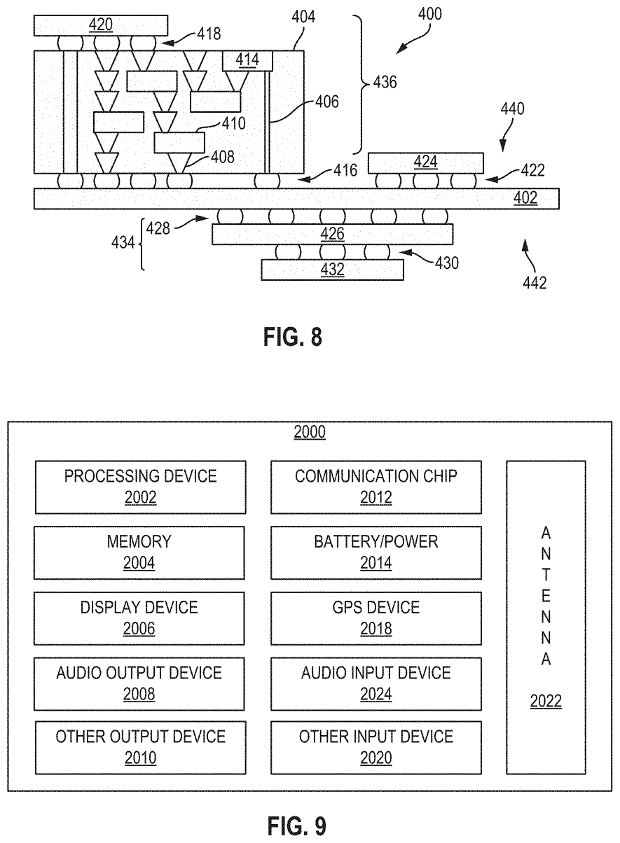

FIG. 8 is a cross-sectional side view of a device assembly 400 that may include any of the thyristors 125 or memory arrays 100 disclosed herein in one or more packages. A “package” may refer to an electronic component that includes one or more IC devices (e.g., the IC devices 1600 discussed above with reference to FIG. 7) that are structured for coupling to other components; for example, a package may include a die coupled to a package substrate that provides electrical routing and mechanical stability to the die. The device assembly 400 includes a number of components disposed on a circuit board 402. The device assembly 400 may include components disposed on a first face 440 of the circuit board 402 and an opposing second face 442 of the circuit board 402; generally, components may be disposed on one or both faces 440 and 442.

In some embodiments, the circuit board 402 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 402. In other embodiments, the circuit board 402 may be a package substrate or flexible board.

The device assembly 400 illustrated in FIG. 8 includes a package-on-interposer structure 436 coupled to the first face 440 of the circuit board 402 by coupling components 416. The coupling components 416 may electrically and mechanically couple the package-on-interposer structure 436 to the circuit board 402 and may include solder balls, male and female portions of a socket, an adhesive, an underfill material, and/or any other suitable electrical and/or mechanical coupling structure.

The package-on-interposer structure 436 may include a package 420 coupled to an interposer 404 by coupling components 418. The coupling components 418 may take any suitable form for the application, such as the forms discussed above with reference to the coupling components 416. Although a single package 420 is shown in FIG. 8, multiple packages may be coupled to the interposer 404; indeed, additional interposers may be coupled to the interposer 404. The interposer 404 may provide an intervening substrate used to bridge the circuit board 402 and the package 420. The package 420 may include one or more thyristors 125 or memory arrays 100, for example. Generally, the interposer 404 may spread a connection to a wider pitch or reroute a connection to a different connection. For example, the interposer 404 may couple the package 420 (e.g., a die) to a ball grid array (BGA) of the coupling components 416 for coupling to the circuit board 402. In the embodiment illustrated in FIG. 8, the package 420 and the circuit board 402 are attached to opposing sides of the interposer 404; in other embodiments, the package 420 and the circuit board 402 may be attached to a same side of the interposer 404. In some embodiments, three or more components may be interconnected by way of the interposer 404.

The interposer 404 may be formed of an epoxy resin, a fiberglass-reinforced epoxy resin, a ceramic material, or a polymer material such as polyimide. In some embodiments, the interposer 404 may be formed of alternate rigid or flexible materials that may include the same materials described above for use in a semiconductor substrate, such as silicon, germanium, and other group III-V and group IV materials. The interposer 404 may include metal interconnects 408 and vias 410, including but not limited to through-silicon vias (TSVs) 406. The interposer 404 may further include embedded devices 414, including both passive and active devices. Such devices may include, but are not limited to, capacitors, decoupling capacitors, resistors, inductors, fuses, diodes, transformers, sensors, electrostatic discharge (ESD) devices, and memory devices (e.g., the thyristors 125 or memory arrays 100). More complex devices such as radio frequency (RF) devices, power amplifiers, power management devices, antennas, arrays, sensors, and microelectromechanical systems (MEMS) devices may also be formed on the interposer 404. The package-on-interposer structure 436 may take the form of any of the package-on-interposer structures known in the art.

The device assembly 400 may include a package 424 coupled to the first face 440 of the circuit board 402 by coupling components 422. The coupling components 422 may take the form of any of the embodiments discussed above with reference to the coupling components 416, and the package 424 may take the form of any of the embodiments discussed above with reference to the package 420, The package 424 may include one or more thyristors 125 or memory arrays 100, for example.

The device assembly 400 illustrated in FIG, 8 includes a package-on-package structure 434 coupled to the second face 442 of the circuit board 402 by coupling components 428. The package-on-package structure 434 may include a package 426 and a package 432 coupled together by coupling components 430 such that the package 426 is disposed between the circuit board 402 and the package 432. The coupling components 428 and 430 may take the form of any of the embodiments of the coupling components 416 discussed above, and the packages 426 and 432 may take the form of any of the embodiments of the package 420 discussed above. Each of the packages 426 and 432 may include one or more thyristors 125 or memory arrays 100, for example.

FIG. 9 is a block diagram of an example computing device 2000 that may include any of the thyristors 125 or memory arrays 100 disclosed herein. A number of components are illustrated in FIG. 9 as included in the computing device 2000, but any one or more of these components may be omitted or duplicated, as suitable for the application. In some embodiments, some or all of the components included in the computing device 2000 may be attached to one or more PCBs (e.g., a motherboard). In some embodiments, various ones of these components may be fabricated onto a single system-on-a-chip (SoC) die. Additionally, in various embodiments, the computing device 2000 may not include one or more of the components illustrated in FIG. 9, but the computing device 2000 may include interface circuitry for coupling to the one or more components. For example, the computing device 2000 may not include a display device 2006 but may include display device interface circuitry (e.g., a connector and driver circuitry) to which a display device 2006 may be coupled. In another set of examples, the computing device 2000 may not include an audio input device 2024 or an audio output device 2008 but may include audio input or output device interface circuitry (e.g., connectors and supporting circuitry) to which an audio input device 2024 or audio output device 2008 may be coupled.

The computing device 2000 may include a processing device 2002 (e.g., one or more processing devices). As used herein, the term “processing device” or “processor” may refer to any device or portion of a device that processes electronic data from registers and/or memory to transform that electronic data into other electronic data that may be stored in registers and/or memory. The processing device 2002 may interface with one or more of the other components of the computing device 2000 (e.g., the communication chip 2012 discussed below, the display device 2006 discussed below, etc.) in a conventional manner. The processing device 2002 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices. In some embodiments, the processing device 2002 may include computing logic that is part of a die that includes embedded memory, such as any of the memory arrays 100 disclosed herein.

The computing device 2000 may include a memory 2004, which may itself include one or more memory devices such as volatile memory (e.g., DRAM), non-volatile memory (e.g., read-only memory (ROM)), flash memory, solid state memory, and/or a hard drive. The memory 2004 may include one or more thyristors 125 or memory arrays 100 or memory devices 200, as disclosed herein. In some embodiments, the memory 2004 may include memory that shares a die with the processing device 2002. This memory may be used as cache memory and may include embedded DRAM (eDRAM) or spin transfer torque magnetic RAM (STT-MRAM).

In some embodiments, the computing device 2000 may include a communication chip 2012 (e.g., one or more communication chips). For example, the communication chip 2012 may be configured for managing wireless communications for the transfer of data to and from the computing device 2000. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

The communication chip 2012 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2012 may operate in accordance with a Global System for Mobile Communication (GSM), General Packet Radio Service (CPRS), Universal Mobile Telecommunications System (UMTS), High Speed Packet Access (HSPA), Evolved HSPA (E-HSPA), or LTE network. The communication chip 2012 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2012 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond, The communication chip 2012 may operate in accordance with other wireless protocols in other embodiments. The computing device 2000 may include an antenna 2022 to facilitate wireless communications and/or to receive other wireless communications (such as AM or FM radio transmissions).

In some embodiments, the communication chip 2012 may manage wired communications, such as electrical, optical, or any other suitable communication protocols (e.g., the Ethernet). As noted above, the communication chip 2012 may include multiple communication chips. For instance, a first communication chip 2012 may be dedicated to shorter-range wireless communications such as Wi-Fi or Bluetooth, and a second communication chip 2012 may be dedicated to longer-range wireless communications such as global positioning system (GPS), EDGE, GPRS, CDMA, WiMAX, LTE, EV-DO, or others. In some embodiments, a first communication chip 2012 may be dedicated to wireless communications, and a second communication chip 2012 may be dedicated to wired communications.

The computing device 2000 may include battery/power circuitry 2014. The battery/power circuitry 2014 may include one or more energy storage devices (e.g., batteries or capacitors) and/or circuitry for coupling components of the computing device 2000 to an energy source separate from the computing device 2000 (e.g., AC line power).

The computing device 2000 may include a display device 2006 (or corresponding interface circuitry, as discussed above). The display device 2006 may include any visual indicators, such as a heads-up display, a computer monitor, a projector, a touchscreen display, a liquid crystal display (LCD), a light-emitting diode display, or a flat panel display.

The computing device 2000 may include an audio output device 2008 (or corresponding interface circuitry, as discussed above). The audio output device 2008 may include any device that generates an audible indicator, such as speakers, headsets, or earbuds,

The computing device 2000 may include an audio input device 2024 (or corresponding interface circuitry, as discussed above), The audio input device 2024 may include any device that generates a signal representative of a sound, such as microphones, microphone arrays, or digital instruments (e.g., instruments having a musical instrument digital interface (MIDI) output),

The computing device 2000 may include a GPS device 2018 (or corresponding interface circuitry, as discussed above). The GPS device 2018 may be in communication with a satellite-based system and may receive a location of the computing device 2000, as known in the art.

The computing device 2000 may include an other output device 2010 (or corresponding interface circuitry, as discussed above). Examples of the other output device 2010 may include an audio codec, a video codec, a printer, a wired or wireless transmitter for providing information to other devices, or an additional storage device.

The computing device 2000 may include an other input device 2020 (or corresponding interface circuitry, as discussed above). Examples of the other input device 2020 may include an accelerometer, a gyroscope, a compass, an image capture device, a keyboard, a cursor control device such as a mouse, a stylus, a touchpad, a bar code reader, a Quick Response (OR) code reader, any sensor, or a radio frequency identification (RFID) reader.

The computing device 2000, or a subset of its components, may have any appropriate form factor, such as a hand-held or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The following paragraphs provide various examples of the embodiments disclosed herein.

Example 1 is an integrated circuit (IC) device, including: a metal portion; and a thyristor on the metal portion, wherein the thyristor includes a stack of alternating p-type and n-type material layers, and the stack is on the metal portion.

Example 2 may include the subject matter of Example 1, andd may further specify that at least one of the p-type and n-type material layers includes a group IV material.

Example 3 may include the subject matter of Example 2, and may further specify that all of the p-type and n-type material layers in the stack include at least one group IV material.

Example 4 may include the subject matter of any of Examples 1-3, and may further specify that at least one of the p-type and n-type material layers includes a group III-V material.

Example 5 may include the subject matter of Example 4, and may further specify that all of the p-type and n-type material layers in the stack include at least one group III-V material.

Example 6 may include the subject matter of any of Examples 1-5, and may further specify that at least one of the p-type and n-type material layers has a thickness between 1 nanometer and 100 nanometers.

Example 7 may include the subject matter of any of Examples 1-6, and may further specify that at least one of the p-type and n-type material layers includes a dopant, and the dopant is present in a concentration between 1e17 atoms/cm³ and 1e21 atoms/cm³.

Example 8 may include the subject matter of any of Examples 1-7, and may further specify that the stack has a width between 10 nanometers and 100 nanometers.

Example 9 may include the subject matter of any of Examples 1-8, and may further specify that the stack has an aspect ratio between 1:5 and 1:20.

Example 10 may include the subject matter of any of Examples 1-9, and may further specify that the stack includes at least four material layers.

Example 11 may include the subject matter of any of Examples 1-10, and may further specify that the metal portion includes gold, palladium, platinum, or nickel.

Example 12 may include the subject matter of any of Examples 1-11, and may further specify that the metal portion is a first metal portion, and the IC device further includes a second metal portion on the stack, wherein the stack is between the first metal portion and the second metal portion.

Example 13 may include the subject matter of Example 12, and may further specify that the first metal portion includes a first conductive line, and the second metal portion includes a second conductive line.

Example 14 may include the subject matter of Example 13, and may further specify that the first conductive line, the second conductive line, and the thyristor are part of a cross-point memory array.

Example 15 may include the subject matter of any of Examples 1-14, and may further specify that the thyristor is one of a plurality of thyristors on the metal portion.

Example 16 may include the subject matter of any of Examples 1-15, and may further specify that the thyristor is a storage element in a memory device.

Example 17 is an integrated circuit (IC) device, including: a device layer; and a back-end memory array, wherein the back-end memory array includes a plurality of thyristors.

Example 18 may include the subject matter of Example 17, and may further specify that the thyristors are storage elements in the back-end memory array.

Example 19 may include the subject matter of any of Examples 1-187, and may further specify that the back-end memory array is a cross-point memory array.

Example 20 may include the subject matter of any of Examples 17-19, and may further specify that individual ones of the thyristors include a group IV material or a group III-V material.

Example 21 may include the subject matter of any of Examples 17-20, and may further specify that individual ones of the thyristors are on a metal portion of the memory array.

Example 22 may include the subject matter of Example 21, and may further specify that the metal portion is a word line or a bit line.

Example 23 is a method of manufacturing an integrated circuit (IC) device, including: forming a metal portion; and forming a stack of alternating p-type and n-type material layers on the metal portion.

Example 24 may include the subject matter of Example 23, and may further specify that the metal portion includes a conductive line or a conductive via.

Example 25 may include the subject matter of any of Examples 23-24, and may further specify that: forming the stack includes forming a layer of dielectric material on the metal portion and forming a recess in the layer of dielectric material; and the stack is formed in the recess.

Example 26 may include the subject matter of Example 25, and may further specify that the layer of dielectric material includes an interlayer dielectric.

Example 27 may include the subject matter of any of Examples 23-26, and may further specify that forming the stack includes performing vapor-liquid-solid growth of the alternating p-type and n-type material layers.

Example 28 may include the subject matter of Example 27, and may further specify that forming the stack includes flowing a dopant during vapor-liquid-solid growth.

Example 29 may include the subject matter of any of Examples 23-28, and may further specify that the metal portion includes gold, palladium, platinum, or nickel.

Example 30 may include the subject matter of any of Examples 23-29, and may further specify that the stack includes a group IV material or a group III-V material.

Example 31 is a computing device, including: a circuit board; and a die communicatively coupled to the circuit board, wherein the die includes a back-end memory array, wherein the back-end memory array includes a plurality of thyristors.

Example 32 may include the subject matter of Example 31, and may further specify that the back-end memory array includes a plurality of thyristors on a metal portion, individual ones of the thyristors include a stack of alternating p-type and n-type material layers, and individual ones of the stacks are on the metal portion,

Example 33 may include the subject matter of Example 32, and may further specify that the back-end memory array is a cross-point memory array.

Example 34 may include the subject matter of any of Examples 32-33, and may further specify that the plurality of thyristors include a group IV or a group III-V material, and the group IV or group III-V material is on a metal portion.

Example 35 may include the subject matter of any of Examples 31-34, and may further specify that the die further includes computing logic.

Example 36 may include the subject matter of Example 35, and may further specify that the computing logic includes a transistor in a device layer of the die.

Example 37 may include the subject matter of any of Examples 31-36, and may further include a wireless communications device coupled to the circuit board,

1. An integrated circuit (IC) device, comprising:
a metal portion; and
a thyristor on the metal portion, wherein the thyristor includes a stack of alternating p-type and n-type material layers, and the stack is on the metal portion.

2. The IC device of claim 1, wherein at least one of the p-type and n-type material layers includes a group IV material.

3. The IC device of claim 2, wherein all of the p-type and n-type material layers in the stack include at least one group IV material.

4. The IC device of claim 1, wherein at least one of the p-type and n-type material layers includes a group III-V material.

5. The IC device of claim 1, wherein at least one of the p-type and n-type material layers includes a dopant, and the dopant is present in a concentration between 1e17 atoms/cm³ and 1e21 atoms/cm³.

6. The IC device of claim 1, wherein the stack has an aspect ratio between 1:5 and 1:20.

7. The IC device of claim 1, wherein the stack includes at least four material layers.

8. The IC device of claim 1 wherein the metal portion includes gold, palladium, platinum, or nickel.

9. An integrated circuit (IC) device, comprising:
a device layer; and
a back-end memory array, wherein the back-end memory array includes a plurality of thyristors.

10. The IC device of claim 9, wherein the thyristors are storage elements in the back-end memory array.

11. The IC device of claim 9, wherein the back-end memory array is a cross-point memory array.

12. The IC device of claim 9 wherein individual ones of the thyristors include a group IV material or a group III-V material.

13. The IC device of claim 9 wherein individual ones of the thyristors are on a metal portion of the memory array.

14. The IC device of claim 13, wherein the metal portion is a word line or a bit line.

15-19. (canceled)

20. A computing device, comprising:
a circuit board; and
a die communicatively coupled to the circuit board, wherein the die includes a back-end memory array, wherein the back-end memory array includes a plurality of thyristors.

21. The computing device of claim 20, wherein the back-end memory array includes a plurality of thyristors on a metal portion, individual ones of the thyristors include a stack of alternating p-type and n-type material layers, and individual ones of the stacks are on the metal portion.

22. The computing device of claim 21, wherein the back-end memory array is a cross-point memory array.

23. The computing device of claim 21, wherein the plurality of thyristors include a group IV or a group III-V material, and the group IV or group III-V material is on a metal portion.

24. The computing device of claim 20, wherein the die further includes computing logic.

25. The computing device of claim 24, wherein the computing logic includes a transistor in a device layer of the die.
